(19) United States
(12) Patent Application Publication
(10) Pub. No.: US 2019/0164775 A1
(43) Pub. Date: May 30, 2019

(54) ETCHING METHOD AND ETCHING APPARATUS

(71) Applicant: Tokyo Electron Limited, Tokyo (JP)

(72) Inventor: Takashi FUSE, Nirasaki City (JP)

(21) Appl. No.: 16/201,434

(22) Filed: Nov. 27, 2018

(30) Foreign Application Priority Data
Nov. 28, 2017 (JP) 2017-228048

(51) Int. Cl. H01L 21/311; H01L 21/67; H01L 21/768; C23C 16/56; C23C 16/48

(52) U.S. Cl. CPC H01L 21/31116; H01L 21/67069; C23C 16/48; C23C 16/56; H01L 21/76822

(57) ABSTRACT

An etching method includes: forming straight-chain molecules containing CFₓ on a substrate to be etched; and irradiating the substrate on which the molecules are formed with an activation gas that activates the CFₓ.

### CROSS-REFERENCE TO RELATED APPLICATION

This application is based upon and claims the benefit of priority from Japanese Patent Application No. 2017-228048, filed on Nov. 28, 2017, the entire contents of which are incorporated herein by reference.

### TECHNICAL FIELD

Various aspects and embodiments of the present disclosure relate to an etching method and an etching apparatus.

### BACKGROUND

There has been conventionally proposed an etching method that performs an etching process on a substrate placed in a processing container by alternately supplying a depositing gas for forming a protective film and an etching gas for promoting etching.

However, the conventional etching method does not control a structure of the protective film deposited on the substrate by the depositing gas. For this reason, the conventional etching method sometimes cannot etch the substrate thinly and uniformly.

### SUMMARY

According to one embodiment of the present disclosure, there is provided an etching method including: forming straight-chain molecules containing CFₓ on a substrate to be etched; and irradiating the substrate on which the molecules are formed with an activation gas that activates the CFₓ.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a partial sectional view showing a configuration of an etching apparatus according to an embodiment.

FIG. 2 is a plan view of a substrate, which is held by a substrate holding part included in the etching apparatus shown in FIG. 1, when viewed from an etching target surface side of the substrate.

FIGS. 3A to 3C are views for explaining an etching method according to the embodiment.

FIG. 4 is a schematic view showing a state of molecules formed on the substrate.

FIG. 5 is a schematic view showing a state in which a film is deposited on a substrate using a conventional depositing gas.

FIG. 6 is a flow chart showing a process flow of an etching program that performs an etching process of the etching method according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of an etching method and an etching apparatus of the present disclosure will be described in detail with reference to the drawings. Throughout the drawings, the same or similar parts and portions are denoted by the same reference numerals. It is to be understood that the present disclosure is not limited by the disclosed embodiments. The embodiments may be used in proper combination unless contradictory to the processing contents.

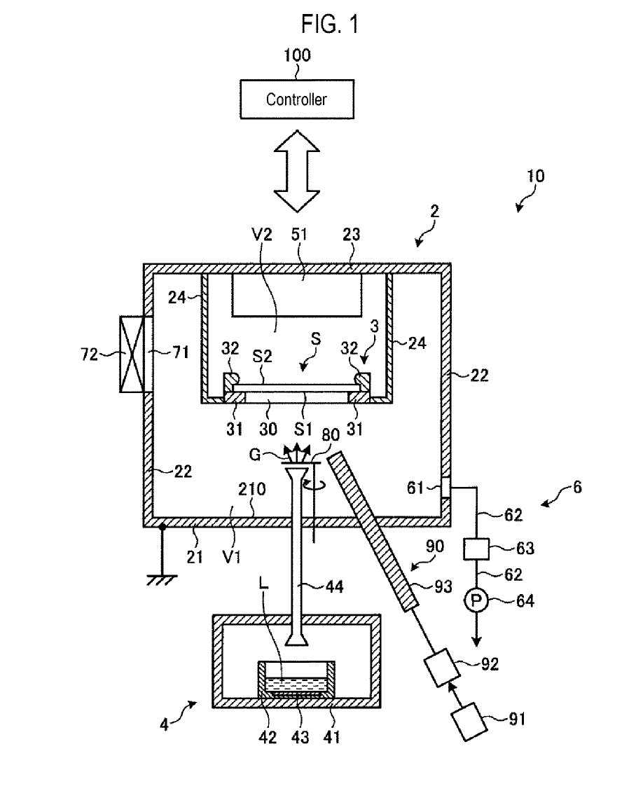

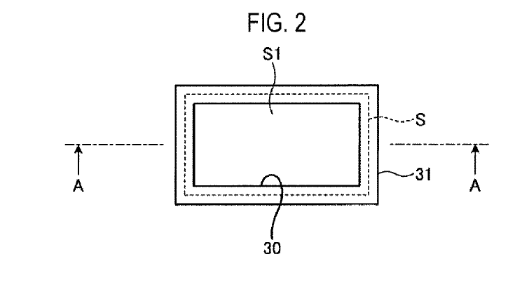

FIG. 1 is a partial sectional view showing a configuration of an etching apparatus according to an embodiment. FIG. 2 is a plan view of a substrate, which is held by a substrate holding part included in the etching apparatus shown in FIG. 1, when viewed from an etching target surface side of the substrate. The cross section of the substrate holding part in FIG. 1 corresponds to the cross section taken along line A-A in FIG. 2.

An etching apparatus 10 according to the embodiment is an apparatus that performs so-called atomic layer etching (ALE) for etching a substrate S thinly and uniformly.

The substrate S has two surfaces. Among the two surfaces, one is an etching target surface S1 to be etched and the other one is a non-etching target surface S2 not to be etched. Material of the substrate S is not particularly limited but may include, for example, inorganic material such as SiO₂ (glass), Si, alumina, ceramics, or sapphire, organic material such as plastics or films, and the like. The substrate S may be a substrate having been subjected to surface treatment such as plasma treatment (plasma etching), wet cleaning treatment, film formation treatment, and the like. In the etching target surface S1 of the substrate S, a pattern, which includes an etching target region to be etched and a non-etching target region not to be etched, is formed. For example, in the etching target surface S of the substrate S, a wiring pattern including a metal layer and an insulating film is formed. The insulating film is an etching target region, while the metal layer is a non-etching target region.

The etching apparatus 10 includes a chamber 2 in which the substrate S is accommodated, a substrate holding part 3 that holds the substrate S in the chamber 2, a raw material gas supply part 4 that supplies a raw material gas G to be deposited on the substrate S into the chamber 2, a substrate heating part 51 that heats the substrate S held by the substrate holding part 3, and an exhaust part 6 that discharges an internal atmosphere of the chamber 2.

As shown in FIG. 1, the chamber 2 includes a bottom wall portion 21, a peripheral wall portion 22 erecting from a peripheral edge of the bottom wall portion 21, and a top wall portion 23 sealing an upper opening of the peripheral wall portion 22.

The substrate holding part 3 includes a frame portion 31 and a chuck portion 32. As shown in FIGS. 1 and 2, the frame portion 31 has an opening 30 that exposes the etching target surface S1 of the substrate S toward an inner wall surface 210 of the bottom wall portion 21 of the chamber 2. The frame portion 31 supports a peripheral edge of the etching target surface S1 of the substrate S and exposes the etching target surface S of the substrate S toward the inner wall surface 210 of the bottom wall portion 21 of the chamber 2 through the opening 30. As shown in FIG. 2, an outer peripheral line and an inner peripheral line of the frame portion 31 have a rectangular shape in a plan view, but may have a different shape (for example, a circular shape or the like) as appropriate. A size of the opening 30 is, for example, 100 mm×50 mm. The chuck portion 32 is rotatable about an end portion of the chuck portion on the side of the frame portion 31. When the substrate S is placed on the frame portion 31, the chuck portion 32 rotates outward in a radial direction of the frame portion 31 and is located at a position (standby position) where the chuck portion 32 does not interfere with the substrate S placed on the frame portion 31. After the substrate S is placed on the frame portion 31, the chuck portion 32 rotates inward in the radial direction of the frame portion 31 and is located at a position (holding position) where the chuck portion 32 holds an outer edge portion of the substrate S supported by the frame portion 31. In this manner, the chuck portion 32 holds the outer edge portion of the substrate S supported by the frame portion 31.

As shown in FIG. 1, the chamber 2 includes a partition wall portion 24 that partitions an internal space of the chamber 2 into a first space V1 where the etching target surface S1 of the substrate S held by the substrate holding part 3 is exposed and a second space V2 where the non-etching target surface S2 of the substrate S held by the substrate holding part 3 is exposed. The partition wall portion 24 extends from the frame portion 31 to the top wall portion 23 of the chamber 2. A loading/unloading port (not shown) is installed in the partition wall portion 24. The first space V1 and the second space V2 are in communication with each other through the loading/unloading port. The substrate S is loaded into and unloaded from the substrate holding part 3 via the loading/unloading port. When the substrate S is not held by the substrate holding part 3, the first space V1 and the second space V2 are in communication with each other through the opening 30 of the frame portion 31. When the substrate S is held by the substrate holding part 3, the opening 30 of the frame portion 31 is closed by the substrate S held by the substrate holding part 3. As a result, a self-assembled monolayer is prevented from being formed on the non-etching target surface S2 of the substrate S held by the substrate holding part 3.

As shown in FIG. 1, the raw material gas supply part 4 includes a gas generation container 41, an organic compound accommodation container 42 installed in the gas generation container 41, and a raw material gas supply pipe 44 for supplying the raw material gas G generated in the gas generation container 41 into the chamber 2.

A predetermined film forming material L is accommodated in the organic compound accommodation container 42. The film forming material L contains an organic compound composed of straight-chain molecules containing CFₓ (x being an arbitrary integer). An example of this CFₓ may include fluorocarbon such as CF₂, CF₄ or the like. When deposited on a substrate, such an organic compound a self-assembled monolayer (hereinafter sometimes referred to as “SAM”). The self-assembled monolayer refers to a monomolecular film formed by self-assembly of molecules, and has good uniformity because molecular orientation is aligned.

For example, the organic compound composed of straight-chain molecules containing CFₓ may have a structure as shown in the following structural formula (1).

CF₃—(CF₂—CF₂—CF₂—O—)ₘ—CH₂—CH₂—Si—(OCH₃)₃(m=10 to 20) (1)

As described above, the film forming material L capable of forming SAM is accommodated in the organic compound accommodation container 42. In the present embodiment, the film forming material L is in a liquid state. For example, the straight-chain molecule shown in the above structural formula (1) is in a liquid state when m=10 to 20.

Further, among the molecules disclosed in WO2016/190047, for example, an organic compound composed of molecules having a straight main chain of (CF₂)₂ to (CF₂)₅, a functional group of alcohol or ether, and an evaporation temperature (or molecular weight) substantially the same as that of the molecules represented by the structural formula (1) may be used as the organic compound composed of straight-chain molecules containing CFₓ.

A heater 43 is installed in the organic compound accommodation container 42. The heater 43 heats and vaporizes the film forming material L at the time of film formation. For example, when a starting temperature at which the straight-chain molecules containing CFₓ included in the film forming material L starts to be vaporized is about 200 degrees C., in the organic compound accommodation container 42, the heater 43 heats and vaporizes the film forming material L at 200 to 400 degrees C. For example, in the organic compound accommodation container 42, the heater 43 heats and vaporizes the film forming material L at 400 degrees C.

The raw material gas G generated by the vaporization of the film forming material L is transferred to the raw material gas supply pipe 44. A shutter 80 is installed at an end portion of the raw material gas supply pipe 44 on the side of the chamber 2. The shutter 80 is rotatable about an end portion of the shutter 80, and switchable between a closed state in which the end portion of the raw material gas supply pipe 44 on the side of the chamber 2 is closed and an open state in which the end portion of the raw material gas supply pipe 44 on the side of the chamber 2 is open. In the open state in which the end portion of the raw material gas supply pipe 44 on the side of the chamber 2 is open, the raw material gas G transferred to the raw material gas supply pipe 44 is supplied into the chamber 2. Specifically, the raw material gas G is supplied into the first space V1 formed between the etching target surface S1 of the substrate S held by the substrate holding part 3 and the inner wall surface 210 of the bottom wall portion 21 of the chamber 2.

The raw material gas G is discharged toward the etching target surface S1 of the substrate S from a leading end of the raw material gas supply pipe 44 extending into the chamber 2 through the bottom wall portion 21 of the chamber 2. That is to say, the raw material gas G is supplied in a direction from the inner wall surface 210 of the bottom wall portion 21 of the chamber 2 toward the etching target surface S1 of the substrate S held by the substrate holding part 3. As a result, the film forming material L in the raw material gas G is more likely to adhere to the etching target surface S1 of the substrate S held by the substrate holding part 3, thereby improving efficiency of formation of SAM on the etching target surface S1 of the substrate S.

The substrate heating part 51 includes a heater such as a resistance heater, a lamp heater (for example, an LED lamp heater), or the like. In the present embodiment, the substrate heating part 51 is installed on the side of the non-etching target surface S2 of the substrate S held in the substrate holding part 3 (that is to say, in the second space V2 where the non-etching target surface S2 of the substrate S is exposed). Therefore, the substrate heating part 51 heats the substrate S from the side of the non-etching target surface S2 of the substrate S.

The substrate heating part 51 heats the substrate S held by the substrate holding part 3 to a predetermined temperature range from the start temperature at which the straight-chain molecules including CFₓ start to be vaporized. For example, the substrate heating part 51 heats the substrate S to a temperature, which is set to be equal to or higher than the start temperature at which the straight-chain molecules including CFₓ start to be vaporized and is equal to or lower than a set temperature of the organic compound accommodation container 42. For example, when the start temperature at which the straight-chain molecules including CFₓ start to be vaporized is about 200 degrees C., the substrate heating part 51 heats the substrate S to 200 to 300 degrees C., specifically, 200 to 250 degrees C., and more specifically, 200 to 230 degrees C. As a result, the straight-chain molecules are formed on the substrate S with good uniformity.

The etching apparatus 10 further includes an irradiation part 90 for irradiating the substrate S with an activation gas that activates CFₓ in the straight-chain molecules formed on the substrate S. For example, the etching apparatus 10 includes, as the irradiation part 90, a gas source 91 for supplying the activation gas, a mass flow controller 92 for controlling a flow rate of the activation gas, and a gas supply pipe 93 for supplying the activation gas into the chamber 2.

The activation gas supplied from the gas source 91 is supplied to one end of the gas supply pipe 93 via the mass flow controller 92. The mass flow controller 92 controls the flow rate of the activation gas supplied to the one end of the gas supply pipe 93. The other end of the gas supply pipe 93 is arranged below the substrate holding part 3 in the chamber 2. In addition, an ion gun is installed in the gas supply pipe 93. The activation gas supplied to the one end of the gas supply pipe 93 is ionized with predetermined energy by the ion gun, and is discharged from the other end of the gas supply pipe 93.

The activation gas may be any gas as long as the activation gas has a weight enough to allow etching and can activate CFₓ in the straight-chain molecules. An example of the activation gas may include a rare gas such as an argon (Ar) gas or the like.

The irradiation part 90 ejects the activation gas from the other end of the gas supply pipe 93 to irradiate the substrate S with the activation gas. The activation gas is ionized with energy at least enough to impart straightness to the etching.

The activation gas with which the substrate S is irradiated activates CFₓ in the straight-chain molecules formed on the substrate S. In addition, the activation gas collides with and etches a film of CFₓ in the straight-chain molecules formed on the substrate S.

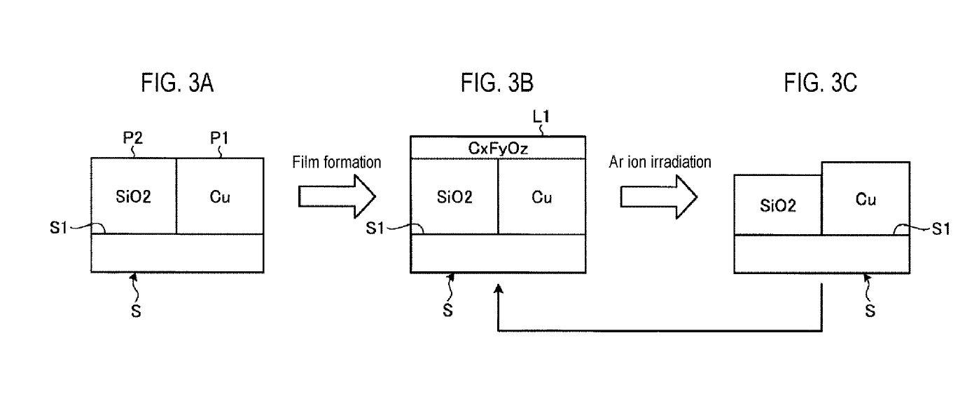

Now, an etching method according to the present embodiment will be described. The etching apparatus 10 according to the present embodiment performs an atomic layer etching process for thinly and uniformly etching the substrate using the etching method according to the present embodiment. FIGS. 3A to 3C are views for explaining the etching method according to the present embodiment FIGS. 3A to 3C show a flow of etching in the etching method according to the present embodiment.

The substrate S has a pattern of a metal layer P1 and an insulating film P2 formed on the etching target surface S1. In the example of FIGS. 3A to 3C, the metal layer P1 is made of Cu and the insulating film P2 is made of SiO₂.

In the etching method according to the present embodiment, the substrate S is heated to a predetermined range of temperature from the start temperature at which the straight-chain molecules containing CFₓ start to be vaporized, and the straight-chain molecules containing CFₓ are deposited on the substrate S by supplying the raw material gas G from the raw material gas supply part 4. As a result, as shown in FIG. 3B, a molecular layer L1 in which the straight-chain molecules containing CFₓ are arranged side by side is formed on the substrate S. Since the straight-chain molecules according to the present embodiment mainly contains carbon (C), fluorine (F), and oxygen (O), the element constitution of the molecular layer L1 is represented by “CₓF_{y}O_{z}” in the example of FIGS. 3A to 3C.

When the substrate S on which the molecular layer L1 is formed is irradiated with Ar ions, the molecular layer L1 is activated by the Ar ions and CF is generated. Further, when the substrate S is irradiated with the Ar ions, physical etching by collision of the Ar ions is performed.

The surface of the insulating film P2 is chemically etched by reaction with CF generated in the molecular layer L1. For example, the insulating film P2 is etched by a reaction as represented by the following chemical expression (2).

SiO₂+CFₓ→SiF₄↑+CO₂↑ (2)

On the other hand, the metal layer P1 is not chemically etched since the metal layer P1 does not react with CF.

That is to say, the insulating film P2 is chemically and physically etched. On the other hand, the metal layer P1 is physically etched. As a result, a difference in etching rate occurs between the insulating film P2 and the metal layer P1. For example, when the substrate S is irradiated with the Ar ions at 1 keV, the metal layer P1 is physically etched only at an etching rate of 22 Å/min. On the other hand, the insulating film P2 is both physically and chemically etched at an etching rate of 30 Å/min. Due to the difference in etching rate between the insulating film P2 and the metal layer P1, the insulating film P2 is etched more than the metal layer P1 per unit time. As a result, as shown in FIG. 3C, the insulating film P2 is etched more than the metal layer P1.

The molecular layer L1 is also physically etched by collision with the Ar ions. When the molecular layer L1 disappears, the metal layer P1 and the insulating film P2 are physically etched only and have little difference in etching rate. For this reason, the substrate S is irradiated with the Ar ions for a predetermined period of time enough to consume the molecular layer L1 completely. This predetermined period of time is obtained in advance by experiments or the like. For example, the irradiation part 90 ionizes an Ar gas with energy of 500 to 1,000 eV and irradiates the substrate S with Ar ions at an ion current of about 100 to 500 [μA] for one minute. In addition, in order to increase controllability of etching, the irradiation part 90 may reduce the ion current and prolong the irradiation time.

In the etching method according to the present embodiment, by depositing the straight-chain molecules containing CFₓ on the substrate S, it is possible to form the molecular layer L1 on the substrate S thinly and uniformly. In the etching method according to the present embodiment, by activating the thin and uniform molecular layer L1 formed as described above, it is possible to etch the substrate S thinly and uniformly. For example, in the etching method according to the present embodiment, the insulating film P2 can be etched in units of, for example, 1 to 2 nm with respect to the metal layer P1.

Further, in the etching method according to the present embodiment, a required amount of etching can be obtained by repeating formation of the molecular layer L1 on the substrate S as shown in FIG. 3B and irradiation of the substrate S with the Ar ions as shown in FIG. 3C.

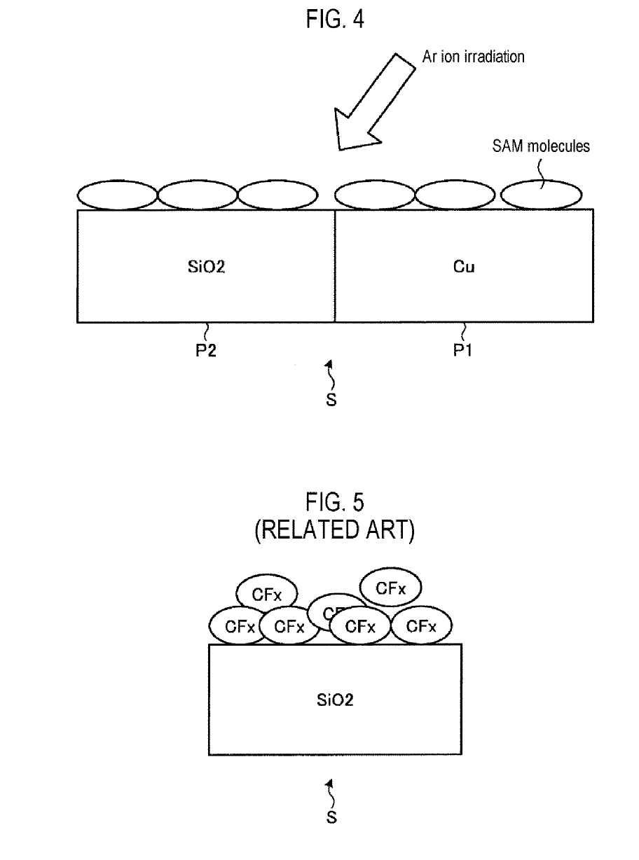

Further, in the etching method according to the present embodiment, in a state in which the temperature of the substrate S is adjusted to a predetermined range of temperature from the start temperature at which the straight-chain molecules containing CFₓ start to be vaporized, the straight-chain molecules are deposited on the substrate S. Among the molecules deposited on the substrate S, molecules not in contact with the substrate S become unstable and are vaporized. As a result, a film (molecular layer L1) in which molecules constituting SAM are arranged side by side is formed on the substrate S. FIG. 4 is a schematic view showing a state of molecules formed on a substrate. As shown in FIG. 4, a film in which molecules constituting SAM are arranged side by side is formed on the substrate S. Since the SAM is a monomolecular film having aligned orientation of molecules, the SAM is formed thinly and uniformly. Thus, in the etching method according to the present embodiment, the substrate S can be etched thin and uniformly.

Here, when deposition using a deposition gas is performed on a substrate as in a conventional etching method, for example, a part of a film deposited on the substrate may be thick and the film may be accordingly formed with poor uniformity. FIG. 5 is a schematic view showing a state in which a film is deposited on the substrate using a conventional depositing gas. The example of FIG. 5 shows a state in which a film of CFₓ molecules is deposited on the substrate S using the depositing gas. As shown in FIG. 5, the CFₓ molecules are stacked and deposited on the substrate S. In this way, according to the conventional etching method, it is not possible to form a thin film of CFₓ molecules with good uniformity. As a result, the conventional etching method cannot etch the substrate thinly and uniformly.

Return to FIG. 1, the exhaust part 6 includes one or more exhaust ports 61 installed in a wall portion (the peripheral wall portion 22 in the present embodiment) of the chamber 2, a pressure regulating valve 63 connected to the exhaust port 61 via an exhaust pipe 62, and a vacuum pump 64 connected to the pressure regulating valve 63 via the exhaust pipe 62. As the vacuum pump 64 sucks the internal atmosphere of the chamber 2 through the exhaust port 61 and the exhaust pipe 62, the internal atmosphere of the chamber 2 is discharged and the internal pressure of the chamber 2 is reduced.

As shown in FIG. 1, a loading/unloading port 71 for loading and unloading the substrate S is installed in a wall portion (the peripheral wall portion 22 in the present embodiment) of the chamber 2. The loading/unloading port 71 can be opened and closed by an airtight shutter 72 such as a gate valve or the like.

The loading/unloading port 71 is connected to a load lock chamber (not shown) via the airtight shutter 72. The substrate S is mounted on the frame portion 31 of the substrate holding part 3 by a transfer arm installed in the load lock chamber.

The overall operation of the etching apparatus 10 configured as above is controlled by a controller 100. The controller 100 is, for example, a computer and controls various parts of the etching apparatus 10. The operation of the etching apparatus 10 is generally controlled by the controller 100.

The controller 100 is constituted by, for example, a computer having a CPU, an MPU, a RAM, a ROM, and the like. Programs for controlling various processes to be executed by the etching apparatus 10 are stored in a storage part such as the RAM or the ROM. For example, an etching program for performing an etching process of an etching method to be described later is recorded on the storage part. A main control part such as the CPU or the MPU controls the operation of the etching apparatus 10 by reading out and executing the programs stored in the storage part such as the RAM or the ROM. The program may be recorded on a computer-readable storage medium or may be installed from the storage medium into the storage part of the controller 100. Examples of the computer-readable storage medium may include a hard disk (HD), a flexible disk (FD), a compact disk (CD), a magneto optical disk (MO), a memory card, and the like.

A flow of etching the substrate S by the etching apparatus 10 will be described below.

The substrate S is mounted on the frame portion 31 of the substrate holding part 3 by the transfer arm installed in the load lock chamber. When the substrate S is mounted on the frame portion 31 of the substrate holding part 3, the etching apparatus 10 closes the airtight shutter 72 and decompresses the interior of the chamber 2 by means of the exhaust part 6. The internal atmosphere of the chamber 2 is maintained at a reduced pressure of, for example, 10 to 10⁻⁹ Pa, specifically 10⁻³ to 10⁻⁶ Pa, by the exhaust part 6.

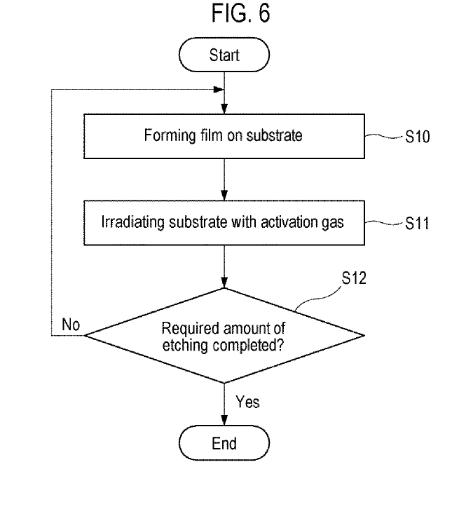

The etching apparatus 10 performs the etching process of the etching method according to the present embodiment on the substrate S. FIG. 6 is a flow chart showing a process flow of an etching program that performs an etching process of the etching method according to the present embodiment.

The etching apparatus 10 deposits straight-chain molecules containing CFₓ on the substrate S (step S10). For example, the controller 100 controls the substrate heating part 51 to heat the substrate S held by the substrate holding part 3 to a predetermined range of temperature from the start temperature at which the straight-chain molecules containing CFₓ start to be vaporized. For example, when the start temperature at which the straight-chain molecules containing CFₓ starts to be vaporized is about 200 degrees C., the substrate heating part 51 heats the substrate S to 200 to 300 degrees C. In addition, the controller 100 turns on the heater 43 of the gas generation container 41 to heat and vaporize the film forming material L by means of the heater 43. The controller 100 rotates the shutter 80 to open the end portion of the raw material gas supply pipe 44 on the side of the chamber 2 and supply the raw material gas G of the film forming material L from the raw material gas supply pipe 44. Thus, a film of straight-chain molecules containing CFₓ is formed on the substrate S. After performing film formation for a predetermined period of time required for the film formation, the controller 100 rotates the shutter 80 to close the end portion of the raw material gas supply pipe 44 on the side of the chamber 2 and stop the supply of the raw material gas G.

Thus, as shown in FIG. 3B, the molecular layer L1 in which the straight-chain molecules containing CFₓ are arranged side by side is formed on the substrate S.

The etching apparatus 10 performs an etching process by irradiating the substrate S with an activation gas for activating CFₓ (step S11). For example, the controller 100 controls the irradiation part 90 to irradiate the substrate S with the activation gas for a predetermined period of time enough to consume the molecular layer L1 completely. The activation gas is ejected and the substrate S is irradiated with the activation gas.

Thus, the substrate S is thinly and uniformly etched as shown in FIG. 3C. As a result, as shown in FIG. 3C, the insulating film P2 is etched more than the metal layer P1.

The etching apparatus 10 determines whether or not a required amount of etching has been completed (step S12). For example, the controller 100 determines whether or not the etching process has been performed a predetermined number of times enough to obtain the required amount of etching. When the etching process has not been performed the predetermined number of times (“No” in step S12), the controller 100 returns the procedure to step S10 and the etching process is performed again. When the etching process has been performed the predetermined number of times (“Yes” in step S12), the controller 100 ends the etching process.

In this manner, the etching apparatus 10 according to the present embodiment forms a film of straight-chain molecules containing CFₓ on the substrate S to be etched. The etching apparatus 10 irradiates the substrate S on which the film of molecules are formed with the activation gas for activating the CFₓ. As a result, the etching apparatus 10 can etch the substrate S thinly and uniformly.

In the etching apparatus 10 according to the present embodiment, the straight-chain molecules containing CFₓ have a chemical structure of CF₃—(CF₂—CF₂—CF₂—O—)ₘ—CH₂—CH₂—Si—(OCH₃)₃ (m=10 to 20). By depositing the straight-chain molecules on the substrate S, it is possible to form a film on the substrate S thinly and uniformly.

In addition, in the etching apparatus 10 according to the present embodiment, the activation gas is an Ar gas. The Ar gas can efficiently activate the CFₓ contained in the straight-chain molecules.

Further, in the etching apparatus 10 according to the present embodiment, the straight-chain molecules containing CFₓ are deposited on the substrate S in a state where the temperature of the substrate S is adjusted to a predetermined range of temperature from the start temperature at which the molecules start to be vaporized. As a result, the etching apparatus 10 can form a film of straight-chain molecules on the substrate S thinly and uniformly.

It has been described in the above embodiment with a case where the straight-chain molecules containing CFₓ are deposited on the etching target surface S1 of the substrate S facing downward and the substrate S is irradiated with the activation gas from below the substrate S. However, the present disclosure is not limited thereto. For example, the straight-chain molecules containing CFₓ may be deposited on the etching target surface S1 of the substrate S facing upward and the substrate S may be irradiated with the activation gas from above the substrate S.

According to the present disclosure in some embodiments, it is possible to etch a substrate thinly and uniformly.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method comprising:
forming straight-chain molecules containing CFₓ on a substrate to be etched; and
irradiating the substrate on which the molecules are formed with an activation gas that activates the CFₓ.

2. The etching method of claim 1, wherein the straight-chain molecules have a chemical structure of CF₃—(CF₂—CF₂—CF₂—O—)ₘ-CH₂—CH₂—Si—(OCH₃)₃ and m is an integer from 10 to 20.

3. The etching method of claim 1, wherein the activation gas is an Ar gas.

4. The etching method of claim 2, wherein the act of forming the straight-chain molecules includes depositing the straight-chain molecules on the substrate in a state where a temperature of the substrate is adjusted to a predetermined range of temperature from a start temperature at which the straight-chain molecules start to be vaporized.

5. An etching apparatus comprising:
a processing container;
a substrate holding part installed in the processing container and configured to hold a substrate to be etched; and
a controller configured to perform the etching method of claim 1.
